(19) United States
(12) Patent Application Publication
(10) Pub. No.: US 2018/0294409 A1
(43) Pub. Date: Oct. 11, 2018

(54) DIRECT FORMATION POROUS MATERIALS FOR ELECTRONIC DEVICES

(71) Applicant: William Marsh Rice University, Houston, TX (US)

(72) Inventors: James M. Tour, Bellaire, TX (US); Yongsung Ji, Houston, TX (US); Seoung-Ki Lee, Houston, TX (US)

(73) Assignee: William Marsh Rice University, Houston, TX (US)

(21) Appl. No.: 15/766,915

(22) PCT Filed: Oct. 7, 2016
(86) PCT No.: PCT/US16/56020

§ 371 Date: Apr. 9, 2018

Related U.S. Application Data
(60) Provisional application No. 62/238,401, filed on Oct. 7, 2015.

(51) Int. Cl. H01L 45/00; H01L 27/24

(52) U.S. Cl. CPC H01L 45/1625; H01L 27/2418; H01L 45/1233; H01L 45/1253; H01L 45/141; H01L 45/1641; H01L 45/146

(57) ABSTRACT

A method for forming an electronic device may comprising the steps of selecting a substrate for an electronic device, and depositing a porous film utilizing physical vapor deposition, dry deposition, evaporative deposition, e-beam evaporation, plasma enhanced chemical vapor deposition, or atomic layer deposition. In some embodiments, a deposition rate, temperature, pressure, or combination thereof may be carefully controlled during deposition to generate the porous film. Further, the depositing of the porous film occurs without the need for further processing. Additional steps may also include depositing an additional layer for the electronic device. In some case, the method may also include depositing and/or patterning a secondary electronic device on top or below the first electronic device.

### RELATED APPLICATIONS

This application claims the benefit of U.S. Provisional Patent Application No. 62/238,401 filed on Oct. 7, 2015, which is incorporated herein by reference.

### FIELD OF THE INVENTION

This invention relates to electronic devices, and more particularly, to direct formation of porous materials for such devices.

### BACKGROUND OF INVENTION

Two-terminal resistive random access memory (RRAM) has been in the limelight for the development of next-generation nonvolatile memory because of its excellent scalability within a simple structure, high switching speed, low programming energy per bit, and low fabrication cost as well as its potential in the flexible electronic systems as compared with Si-based field-effect transistor technology. Various patent applications relating to such technology can be found PCT Pub. No. WO 2013/032983, U.S. Pre-Grant Pub. No. 2015-0162381, PCT Pub. No. WO 2012/112769, U.S. Pre-Grant Pub. No. 2014-0048799, U.S. Pre-Grant Pub. No. 2011/0038196, Pub. No. WO 2015/077281, and U.S. Pre-Grant Pub. No. 2016-0028004, and the entirety of each of the aforementioned applications is incorporated herein by reference. It was previously reported that a unipolar non-volatile memory (NVM) utilizing SiOₓ (1≤x<2, x is the oxygen content) RRAM material, one of the most common, well studied, best controlled in growth and content, and low-priced materials in the semiconductor industry, has shown desirable attractive performance metrics, such as optimal switching performance, fast switching speed, and low energy consumption by low on-current for future memory applications.

However, despite attractive properties of SiOₓ unipolar memory, the structures have various limitations, including the following: (a) lower than desired endurance cycles in some instances; and (b) high electroforming voltage (e.g., >20 V). In order to address the aforementioned limitations, electronic devices utilizing porous materials have been contemplated.

However, while porous SiOₓ unipolar memory is an improvement, there are still critical processing issues to realize, such as for the three-dimensional stacked high density memory architectures. Issues that may arise include the following: (a) Since the solution based anodization process for the porous structure is sensitive to solution concentration, it causes difficulty in reproducing pore size and porosity. (b) The complicated anodization tool and process are not compatible with typical CMOS technology fabrication facilities. (c) Reproducing porous structures and porosity are difficult in a patterned bottom electrode for high density arrayed device architectures because of non-uniform electric fields on patterned electrode. (e) In addition, the SiOₓ layer as well as additional selector layer could be damaged during multilayer film stacking processes during anodization, which limit multi-layer stacked device architectures. Various aspects of the present disclosure address the aforementioned limitations.

### SUMMARY OF INVENTION

In one embodiment, a method for forming an electronic device may comprising the steps of selecting a substrate, wherein the substrate includes a bottom electrode for a primary electronic device; and depositing a porous film on top of the bottom electrode utilizing physical vapor deposition, dry deposition, evaporative deposition, e-beam evaporation, plasma enhanced chemical vapor deposition, or atomic layer deposition. In some embodiments, a deposition rate, temperature, pressure, or combination thereof may be carefully controlled during deposition to generate the porous film. Further, the depositing of the porous film occurs without the need for further processing, or in other words, the formation of the porous film may be considered to be direct formation. The method may also include depositing an additional layer for the primary electronic device, wherein the additional layer is a top electrode. In some embodiments, the method may further include optionally etching to expose the bottom electrode. In yet another embodiment, the method may include depositing and/or patterning a secondary electronic device on top or below the primary electronic device. The first and second electronic devices may be selected from a memory, switch, resistor, diode, transistor or the like.

The foregoing has outlined rather broadly various features of the present disclosure in order that the detailed description that follows may be better understood. Additional features and advantages of the disclosure will be described hereinafter.

### BRIEF DESCRIPTION OF THE DRAWINGS

For a more complete understanding of the present disclosure, and the advantages thereof, reference is now made to the following descriptions to be taken in conjunction with the accompanying drawings describing specific embodiments of the disclosure, wherein:

FIG. 1 shows a method for direct deposition of porous materials for an electronic device.

FIGS. 2A-2B respectively show reflective index (left) and IR absorption spectra (right) of porous SiOₓ film as a function of deposition rate.

FIGS. 3A-3C show electrical results of direct deposited porous SiOₓ based memory for electroforming process, I-V characteristic and retention test.

FIG. 4A-4B shows a schematic illustration and representative switching I-V characteristics of 1D-1R memory device.

### DETAILED DESCRIPTION

Refer now to the drawings wherein depicted elements are not necessarily shown to scale and wherein like or similar elements are designated by the same reference numeral through the several views.

Referring to the drawings in general, it will be understood that the illustrations are for the purpose of describing particular implementations of the disclosure and are not intended to be limiting thereto. While most of the terms used herein will be recognizable to those of ordinary skill in the art, it should be understood that when not explicitly defined, terms should be interpreted as adopting a meaning presently accepted by those of ordinary skill in the art.

It is to be understood that both the foregoing general description and the following detailed description are exemplary and explanatory only, and are not restrictive of the invention, as claimed. In this application, the use of the singular includes the plural, the word “a” or “an” means “at least one”, and the use of “or” means “and/or”, unless specifically stated otherwise. Furthermore, the use of the term “including”, as well as other forms, such as “includes” and “included”, is not limiting. Also, terms such as “element” or “component” encompass both elements or components comprising one unit and elements or components that comprise more than one unit unless specifically stated otherwise.

The systems and methods discussed herein relate to the direct formation of porous materials for electronic devices. As utilized herein, “direct” in reference to formation or deposition refers to the creation of a porous material layer without the need for further processing. For example, other methods that would be considered to be “non-direct” involve the initial deposition of the material layer that is nonporous, followed an etching step cause the formation of pores in the material layer. In contrast, the direct formation or direct deposition discussed herein is able to form pores during the deposition steps without the need for subsequent processing.

In some embodiments, the methods pertain to forming porous materials by directly depositing a porous layer onto a substrate. The substrate may be any suitable substrate, such as, but not limited to, a silicon wafer, an electrode, a substrate with a secondary electronic device (e.g. diode, transistor, memory, resistor, switch, etc.), combinations thereof, or the like. Further embodiments pertain to the porous materials that are formed by the methods discussed further herein. In some embodiments, the porous materials can be utilized as components of various electronic devices, such as a switch, resistor, memory, or the like. For instance, in some embodiments, the porous materials are utilized as materials for multi-stack electronic or switching devices. In some embodiments, the methods discussed herein may be utilized to form a primary electronic device utilizing the porous layer. In some embodiments, the electronic device utilizing the porous layer may be part of a multi-stacked electronic device or switching device. Further, some embodiments may incorporated this primary electronic device utilizing the porous layer with a secondary electronic device, such as, but not limited to, transistors, diodes, memory, switches, resistors, or the like. As nonlimiting examples, the method may be utilized to form one diode-one resistor (1D-1R), one transistor-one resistor (1T-1R), or one selector-one resistor (1S-1R) devices from the primary and secondary electronic devices. In some embodiments, the electronic device(s) may have three-dimensional multi-stacked configurations. Further embodiments pertain to electronic devices that contain the porous materials.

The formed porous film or layer may be selected from any suitable materials. As a nonlimiting example, the materials for the porous layer may be switching material(s) for an electronic device, such as a memory, switch, or resistor. In some embodiments, the porous film to be formed is SiOₓ, where 0≤x≤2. In some embodiments, the porous film to be formed may be selected from a metal oxide or metal chalcogenide. In some embodiments, the porous film may be tantalum oxide. In some embodiments, the tantalum oxide may be selected from Ta₂O₅₋ₓ, TaO, or TaOₓ where 0≤x≤5. In some embodiments, the porous film to be formed may be selected from titanium oxide, aluminum oxide, vanadium oxide, or the like. It should be noted that the metal oxides discussed above may be any suitable form of such oxides, including non-stoichiometric forms of the oxides. Nonlimiting examples vanadium(II) oxide or vanadium monoxide (VO), vanadium(III) oxide, vanadium sesquioxide, or trioxide (V₂O₃), vanadium(IV) oxide or vanadium dioxide (VO₂), vanadium(V) oxide or vanadium pentoxide (V₂O₅), TiₓO_{y} where 0<x≤2 and 0<y≤3 (e.g. TiO₂, TiO, Ti₂O₃, etc.), TiₙO₂ₙ₋₁ where n ranges from 3-9 (e.g. Ti₃O₅, Ti₄O₇, etc.), Al₂O₃, or the like. In some embodiments, the porous film to be formed may be selected from TiₓO_{y} where 0<x≤2 and 0<y≤3, TiₙO₂ₙ₋₁ where n ranges from 3-9, VₓO_{y} where 0<x≤2 and 0<y≤5, AlₓO_{y} where 0<x≤2 and 0<y≤3, or the like.

Various methods may be utilized to form the porous materials. For instance, in some embodiments, a porous layer is directly deposited onto a substrate by various deposition methods. In some embodiments, the deposition occurs by using a physical vapor deposition method. In some embodiments, the deposition occurs by using a dry deposition method. In some embodiments, the deposition occurs by evaporative deposition. In some embodiments, the deposition occurs by e-beam evaporation. In some embodiments, the deposition occurs by plasma enhanced chemical vapor deposition or atomic layer deposition. In some embodiments, the porous layer is directly deposited using an e-beam evaporation apparatus.

In some embodiments, the porosity of a deposited layer is controlled by controlling the deposition rate, temperature and/or chamber pressure. In some embodiments, no further processing steps are required after deposition to make the layer porous or the formation of deposition process is direct. For instance, in some embodiments, an anodic etching process is not required after deposition.

In some embodiments, a porous layer is deposited onto a surface of an electrode (e.g., a bottom Pt electrode). In some embodiments, a top electrode is then deposited onto a surface of the porous SiOₓ layer. In some embodiments, the columnar porous structure produced by the porous layer formation may be desirable to fully fill during deposition of the top electrode, which may be advantageous to an electroformation process.

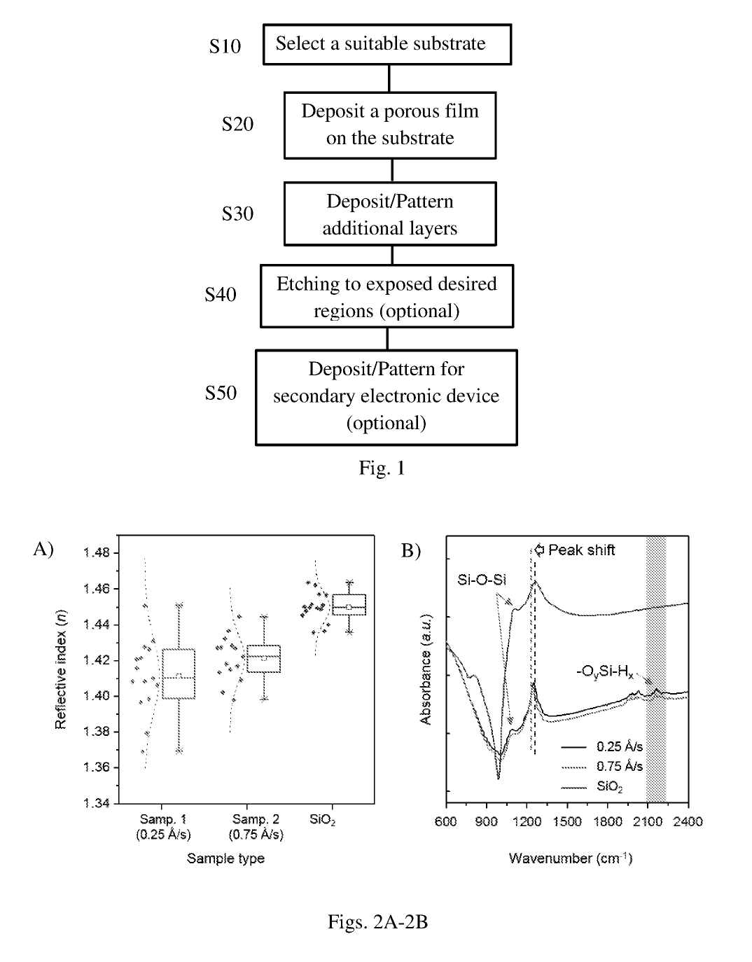

In some embodiments, a method for direct formation of porous materials for an electronic device may include the following steps as shown in FIG. 1. In step S10, a suitable substrate may be selected. As discussed previously, the substrate may be any suitable substrate. As a nonlimiting example, the substrate may include a bottom electrode and the substrate may even include a secondary electronic device such as a diode, transistor, switch, resistor, or memory. Thus, it is apparent that this step may also include any deposition or processing steps necessary to produce a desired substrate (e.g. deposition of layers, such as a bottom electrode, for the primary electronic device that will utilized the porous layer, deposition/pattern of the components for the secondary electronic device, or both). For example, depositing and/or patterning for a secondary electronic device may be performed before the substrate is prepared for deposition of a primary electronic device.

In step S20, a porous film is deposited on top of the substrate utilizing any suitable deposition process discussed above, such as physical vapor deposition, dry deposition, evaporative deposition, e-beam evaporation, plasma enhanced chemical vapor deposition, or atomic layer deposition. It should be noted that the deposition of the porous film occurs without the need for further processing, whereas other techniques for generating a porous film of a memory device utilize anodic etching. In this deposition step, the deposition rate, temperature, pressure may all be carefully controlled to generate the porous film desired. In some embodiments, the deposition rate of the porous film may be between 0.1-0.5 Å/s. In some embodiments, the temperature during deposition of the porous film may be equal to or less that 100° C. In some embodiments, the chamber pressure during deposition of the porous film may be equal to or less than 5e-6 Torr. In some embodiments, the deposition rate, temperature, and/or chamber pressure during the deposition of the porous layer may be in any of the above noted ranges. Without being bound by theory, it is believed that by carefully controlling various deposition parameters discussed above, the desired materials can be directly deposited on substrate with a columnar pore structure, which is sometimes referred to as a self-shadowing effect. It shall be apparent that this porous film is utilized as part of a primary electronic device, such as a switch, resistor, memory, transistor, diode, or the like. As a nonlimiting example, the deposited porous film may be utilized to form a memory, resistor, or switch, which may comprise the porous layer sandwiched between two conductive layers. In embodiments where a secondary electronic device is present on the substrate prior to deposition step S20, this deposition step may be utilized to form the primary electronic device on top of the secondary electronic device. For example, in embodiments involving 1D-1R (e.g. FIG. 4A), 1T-1R, or 1S-1R devices, the secondary electronic device (e.g. diode or transistor) may be previously present on the substrate prior to the deposition of the porous film.

To advance formation of the primary electronic device that utilizes the porous film, in step S30, additional layer(s) for the primary electronic device may be deposited utilizing any suitable known deposition methods. The one or more additional layers for the primary electronic device may be a metal or conductive layer, semiconductive layer, dielectric layer, insulator layer, or a combination thereof in accordance with the electronic device desired. In some embodiments, the primary electronic device to be formed is a switch, resistor, or memory, and thus, the additional layer deposited in step S30 may be a top electrode. In some embodiments, this step may also involve masking, etching, lithography, or the like to achieve a desired pattern for one of the additional layer or several of the additional layers. As a nonlimiting example, photo-mask or shadow metal mask methods may be utilized to deposit a top electrode in a patterned area on top of the porous film to form a switch, resistor, or memory with the porous film sandwiched between top and bottom electrodes. In embodiments where a different electronic device is desired, other additional layer(s) may be deposited/patterned layers prior to deposition of the top electrode, which may also be completed during step S30.

In step S40, optional etching may be performed to expose desired region(s). As a nonlimiting example, etching may be performed to expose the bottom electrode (e.g. Pt electrode) of the primary electronic device.

In some cases, it may be desirable to have the secondary electronic device deposited on top of the primary electronic device rather than below the primary electronic device. As such, in optional step S50, deposition and/or patterning for such a secondary electronic device may be performed. As a nonlimiting example, after steps S10-S40, the deposited porous film may be sandwich between two conductive layers to form the primary electronic device, such as a memory, resistor or switch. In embodiments where a 1D-1R, 1T-1R, or 1S-1R devices are desired, the secondary electronic device (e.g. diode or transistor) can be formed on top of the primary electronic device in step S50 by depositing and/or patterning metal or conductive layer(s), semiconductive layer(s), dielectric layer(s), and/or insulator layer(s) necessary to form such devices. As a nonlimiting example, in step S50 metal and semiconductor layers can be deposited to form a diode, and the layers may also be patterned if desired.

In some embodiments, it may be desirable to form additional stacked electronic devices. As such, it shall be understood that steps S10-S50 may be repeated a desired to form these additional stacked electronic devices.

The porous materials can have various advantageous properties. In some embodiments, the operation yield of electronic device containing the porous materials produced by the methods discussed herein may be high, such as, but not limited to 50% or greater. In some embodiments, the operation yield of electronic device containing the porous materials may be 60% or greater. In some embodiments, the operation yield of electronic device containing the porous materials may be 70% or greater. In some embodiments, the operation yield of electronic device containing the porous materials may be 80% or greater. For instance, in some embodiments, the operation yield of memory in a 64 bit arrayed device containing the porous SiOₓ materials produced by the methods discussed herein was improved significantly from 34% (22/64) to 88% (58/64).

Moreover, it shall be recognized that the methods provide a feasible method to realize a one diode-one resistor (1D-1R) device array (64 bit) by forming a porous SiOₓ layer in accordance with the methods discussed herein. Thus, as a nonlimiting example, it can be seen that the substrate selected in step S10 of the method discussed above may include a diode and bottom electrode prior to deposition of the porous material layer in step S20. Subsequently, a top electrode may be deposited/patterned in step S30, and etching may be performed in step S40 to expose the bottom electrode, thereby resulting in a 1D-1R device.

In some embodiments, the methods discussed above are utilized to form a porous unipolar memory cell with a typical layered structure. As a nonlimiting example, a porous SiOₓ (0≤x≤2) layer may be sandwiched between the top electrode (TE) and bottom electrode (BE). After the memory unit is electroformed into a switchable state, a moderate voltage pulse (e.g., 3 to 5 V) can set/write the unit into a low-resistance (on) state while a higher voltage pulse (e.g., >6 V) can reset/erase the unit to a high-resistance (off) state. Once programmed, the resistance states (e.g. both on and off states) are nonvolatile. The memory readout shares the same electrode as the programming electrode, only that at a lower voltage (e.g. <3 V), the memory is read. The memory state can be read nondestructively. Due to the similarity to pure SiOₓ memory operation, details of the memory programming and readout in a SiOₓ memory unit are not discussed in detail here, but can be found in previously referenced patents.

The methods may have numerous variations. Nonlimiting exemplary variations are disclosed herein: (1) The thickness of the layers (e.g., SiOₓ and electrodes) in the structures and the deposition can be varied as desired to obtain optimum performance. (2) The deposition rate and chamber pressure of e-beam evaporation can be varied to tailor the pore size and porosity of the porous SiOₓ layer. (3) e-beam evaporation can be substituted with other methods of evaporation of SiOₓ, provided that the chamber pressure can be made to be sufficiently low to produce the desired porosity. (4) Chemical and physical treatments on surfaces can be varied to obtain optimum performances for making porous SiOₓ. A nonlimiting examples, an oxygen plasma treatment may be performed the substrate to clean the surface; chemical and mechanical polishing (CMP) may be performed on the metal electrode coated substrate to make a uniform surface, or the like. (5) The x value in SiOₓ can be varied (e.g., 0≤x≤2) to obtain the optimum performance from the memories. Similarly, the oxygen content in tantalum oxide, metal oxides, metal chalcogenides, or any other memory layers can be varied as well to achieve desired performance. (6) The feature size and form (e.g. line width and/or sample size) of the cells can be varied to obtain optimum performance from the memories. (7) Multi-bit storage capability could be obtained in a porous SiOₓ memory unit wherein there is more than just a 0 and 1 state, but 0, 1, 2, 3 and even 4 or higher number of states. As a nonlimiting example, porosity between 10-30% may be suitable for multi-bit storage. (8) A multi-stacking structure (e.g., 3D from stacked 2D) can be explored in a porous memory for ultra-dense memory arrays. (9) The porous material is not limited to SiOₓ, and can be any suitable metal oxides, metal chalcogenides, or the like. For example, any of the materials discussed in the following patents may be viable options: PCT Pub. No. WO 2013/032983, U.S. Pre-Grant Pub. No. 2015-0162381, PCT Pub. No. WO 2012/112769, U.S. Pre-Grant Pub. No. 2014-0048799, U.S. Pre-Grant Pub. No. 2011/0038196, Pub. No. WO 2015/077281, and U.S. Pre-Grant Pub. No. 2016-0028004 which are incorporated herein by reference. As a nonlimiting example of an alternative, a metal oxide such as tantalum oxide may be utilized. (10) In some embodiments, the systems and methods discussed herein can be utilized to form transparent and/or flexible electronic devices. (11) The devices formed by the methods discussed herein can have various architectures, such as, but not limited to, crossbar architectures, three-dimensional architectures, and combinations thereof.

The following examples are included to demonstrate particular aspects of the present disclosure. It should be appreciated by those of ordinary skill in the art that the methods described in the examples that follow merely represent illustrative embodiments of the disclosure. Those of ordinary skill in the art should, in light of the present disclosure, appreciate that many changes can be made in the specific embodiments described and still obtain a like or similar result without departing from the spirit and scope of the present disclosure.

Various methods may be utilized to fabricate the porous materials for an electronic device. A nonlimiting example of a suitable fabrication procedure for a SiOₓ memory device can involve the following steps:

(1) The porous SiOₓ cells may be fabricated on p-type Si(100) wafers (e.g. 1.5 cm×1.5 cm) covered with thermally grown SiO₂ (e.g. 300 nm-thick). (2) A Pt bottom electrode was deposited on the substrate by sputtering or e-beam evaporation after a typical cleaning process with acetone, isopropyl alcohol, and deionized (DI) water by ultra-sonication (bath) for 3 minutes. (3) Then, the porous SiOₓ film (e.g. 30-50 nm) was deposited on the bottom electrode by using e-beam evaporation. As a nonlimiting example, the deposition rate, temperature and chamber pressure was maintained respectively at ˜0.5 Å/s, 25° C. and ˜1×10⁻⁶ Torr. Due to relatively low chamber temperature (e.g. T<0.3 Tₘ where Tₘ is the melting temperature in kelvin) and pressure, the porous SiOₓ film was directly deposited on bottom electrode having columnar pore structure, which is called a self-shadowing effect. (4) Using photo-mask or shadow metal mask methods, the top electrode was deposited on the patterned area. (5) Finally, reactive-ion etching was performed to expose the bottom Pt electrode.

The porous SiOₓ materials can have various applications. For instance, in some embodiments, a porous unipolar SiOₓ memory formed by the methods can be used for the fabrication of stable two-terminal nonvolatile memories for low electroforming voltages and 3D stackable device integration while maintaining their intrinsic favorable switching properties.

The porous SiOₓ materials can have various novel aspects. The major advantages of direct formation of porous SiOₓ layer are summarized as compared with the traditional porous SiOₓ memory systems, which are usually conducted with an anodic etching process.

Since the porosity was controlled by evaporation rate and chamber pressure during physical vapor deposition, this direct deposition of the porous material layer utilizing these methods does not need any extra electrodes, anodization tools or cleaning steps to make porous films. This advantage is important, because it permits continuous CMOS processes to fabricate the entire porous memory device.

FIGS. 2A-2B shows the reflective index (left) and IR absorption spectra (right) of porous SiOₓ film as a function of deposition rate.

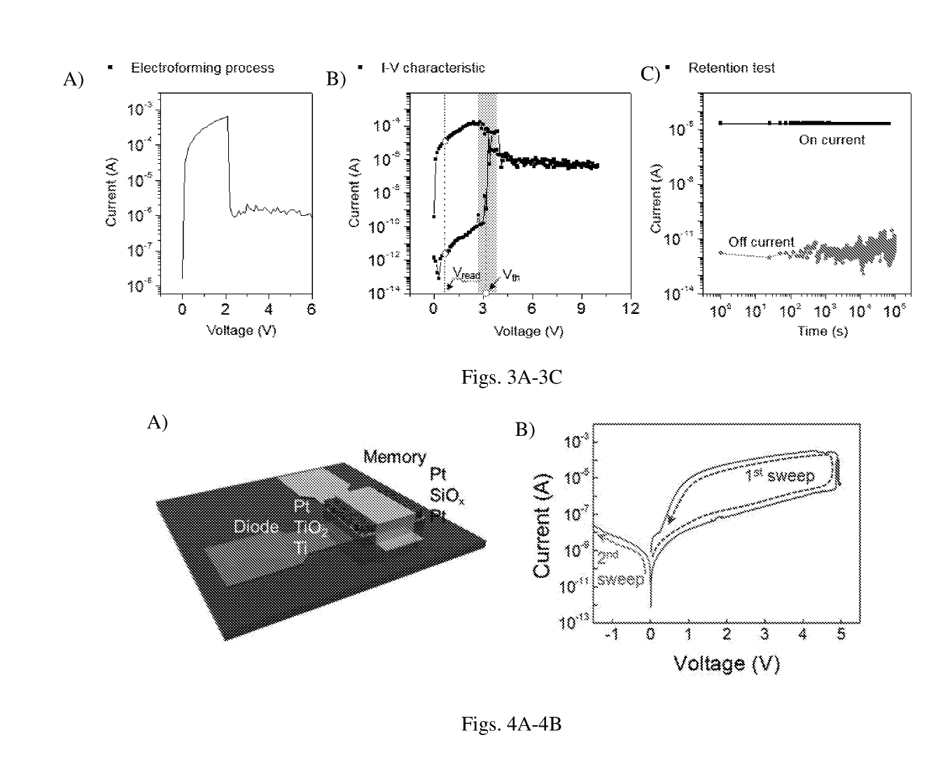

The dry and vacuum process may utilize well-developed conventional deposition equipment, such as e-beam evaporators, which improves the uniformity of the SiOₓ film and the yield of working devices from 34% to 88% in comparison to techniques utilizing etching to generate the pores, while maintaining advantage of porous memory characteristics. The yield may reach near 100% upon optimization. The porous SiOₓ memory exhibited extremely low electroforming voltage (e.g. <3 V) and excellent retention (e.g. ≥10⁵ s). In addition, moderate voltage pulses (e.g. between 3 to 5 V) can set/write the unit into low-resistance state while higher voltage pulse (e.g. ≥6 V) can reset/erase the unit to a high-resistance (off) state (FIGS. 3A-3C).

FIGS. 3A-3C show electrical results of direct deposited porous SiOₓ based memory for electroforming process, I-V characteristic and retention test.

In some embodiments, the methods are suitable for high density memory fabrication via three dimensional multi stacked configurations. To implement a high density memory device, it is preferable to have homogeneous and heterogeneous integration, such as in 1D-1R, 1T-1R, 1S-1R, and the like. However, previous porous SiOₓ memory methods had difficulty yielding multi-stacked devices because the anodic electrochemical treatment damaged other nearby components. On the contrary, the methods discussed herein do not affect the other devices. Thus, the multi-layer can be stacked as desired (e.g., FIGS. 4A-4B). FIGS. 4A-4B respectively show a schematic illustration and representative switching I-V characteristics of 1D-1R memory device.

Embodiments described herein are included to demonstrate particular aspects of the present disclosure. It should be appreciated by those of skill in the art that the embodiments described herein merely represent exemplary embodiments of the disclosure. Those of ordinary skill in the art should, in light of the present disclosure, appreciate that many changes can be made in the specific embodiments described and still obtain a like or similar result without departing from the spirit and scope of the present disclosure. From the foregoing description, one of ordinary skill in the art can easily ascertain the essential characteristics of this disclosure, and without departing from the spirit and scope thereof, can make various changes and modifications to adapt the disclosure to various usages and conditions. The embodiments described hereinabove are meant to be illustrative only and should not be taken as limiting of the scope of the disclosure.

What is claimed is:

1. A method for forming an electronic device, the method comprising:
selecting a substrate, wherein the substrate includes a bottom electrode for a primary electronic device;
depositing a porous film on top of the bottom utilizing physical vapor deposition, dry deposition, evaporative deposition, e-beam evaporation, plasma enhanced chemical vapor deposition, or atomic layer deposition, wherein the depositing of the porous film occurs without the need for further processing; and
depositing an additional layer for the primary electronic device, wherein the additional layer is a top electrode.

2. The method of claim 1 further comprising the step of etching to expose the bottom electrode.

3. The method of claim 1, wherein the primary electronic device is part of a multi-stack electronic or switching device.

4. The method of claim 1, wherein the substrate further comprises a secondary electronic device selected from a resistor, switch, transistor, diode, or memory.

5. The method of claim 4, wherein the primary electronic device and the secondary electronic device form a one diode-one resistor (1D-1R) device, one transistor-one resistor (1T-1R) device, or one selector-one resistor (1S-1R).

6. The method of claim 1, wherein the porous film deposited is SiOₓ, where 0≤x≤2.

7. The method of claim 1, wherein the porous film deposited is a porous metal oxide, a porous metal chalcogenide, a porous tantalum oxide, a porous titanium oxide, a porous aluminum oxide, or a porous vanadium oxide.

8. The method of claim 7, wherein the porous film deposited is
Ta₂O₅₋ₓ, TaO, or TaOₓ, where 0≤x≤5,
TiₓO_{y} where 0<x≤2 and 0<y≤3,
TiₙO₂ₙ₋₁ where n ranges from 3-9,
AlₓO_{y} where 0<x≤2 and 0<y≤3, or
VₓO_{y} where 0<x≤2 and 0<y≤5.

9. The method of claim 1, further comprising the step of depositing and/or patterning a secondary electronic device on top of the primary electronic device.

10. The method of claim 9, wherein the primary electronic device and the secondary electronic device form a one diode-one resistor (1D-1R) device, one transistor-one resistor (1T-1R) device, or one selector-one resistor (1S-1R).

11. The method of claim 1, wherein a deposition rate, temperature, pressure, or combination thereof are carefully controlled during the depositing of the porous film to generate the porous film.

12. The method of claim 11, wherein the deposition rate is between 0.1-0.5 Å/s; the temperature is equal to or less that 100° C., or the pressure is equal to or less than 5e-6 Torr.

13. A method for forming an electronic device, the method comprising:
selecting a substrate, wherein the substrate includes a bottom electrode for a primary electronic device;
depositing a porous film on top of the bottom electrode utilizing physical vapor deposition, dry deposition, evaporative deposition, e-beam evaporation, plasma enhanced chemical vapor deposition, or atomic layer deposition, wherein a deposition rate, temperature, pressure, or combination thereof are carefully controlled during deposition to generate the porous film; and
depositing an additional layer for the primary electronic device, wherein the additional layer is a top electrode.

14. The method of claim 13, wherein the substrate further comprises a secondary electronic device selected from a resistor, switch, transistor, diode, or memory, and
the primary electronic device is part of a multi-stack electronic or switching device.

15. The method of claim 14, wherein the primary electronic device and the secondary electronic device form a one diode-one resistor (1D-1R) device, one transistor-one resistor (1T-1R) device, or one selector-one resistor (1S-1R).

16. The method of claim 13, wherein the porous film deposited is SiOₓ, where 0≤x≤2.

17. The method of claim 13, wherein the porous film deposited is a porous metal oxide, a porous metal chalcogenide, a porous tantalum oxide, a porous titanium oxide, a porous aluminum oxide, or a porous vanadium oxide.

18. The method of claim 17, wherein the porous film deposited is
Ta₂O₅₋ₓ, TaO, or TaOₓ, where 0≤x≤5,
TiₓO_{y} where 0<x≤2 and 0<y≤3,
TiₙO₂ₙ₋₁ where n ranges from 3-9,
AlₓO_{y} where 0<x≤2 and 0<y≤3, or
VₓO_{y} where 0<x≤2 and 0<y≤5.

19. The method of claim 13, further comprising the step of depositing and/or patterning a secondary electronic device on top of the primary electronic device.

20. The method of claim 19, wherein the primary electronic device and the secondary electronic device form a one diode-one resistor (1D-1R) device, one transistor-one resistor (1T-1R) device, or one selector-one resistor (1S-1R).

21. The method of claim 13, wherein the depositing of the porous film occurs without the need for further processing.

22. The method of claim 13, wherein the deposition rate is between 0.1-0.5 Å/s; the temperature is equal to or less that 100° C., or the pressure is equal to or less than 5e-6 Torr.
